(19) United States
(12) Patent Application Publication
(10) Pub. No.: US 2025/0127020 A1
(43) Pub. Date: Apr. 17, 2025

(54) DISPLAY MODULE AND PREPARATION METHOD THEREFOR, AND DISPLAY DEVICE

(71) Applicants: Yunnan Invensight Optoelectronics Technology Co., Ltd., Yunnan (CN); BOE Technology Group Co., Ltd., Beijing (CN)

(72) Inventors: Zhijian ZHU, Beijing (CN); Pengcheng LU, Beijing (CN); Shengji YANG, Beijing (CN); Kuanta HUANG, Beijing (CN); Xiaochuan CHEN, Beijing (CN); Qian WU, Beijing (CN); Longfei FAN, Beijing (CN); Dacheng ZHANG, Beijing (CN)

(21) Appl. No.: 18/293,381

(22) PCT Filed: Oct. 21, 2021
(86) PCT No.: PCT/CN2021/125420

§ 371 Date: Jan. 30, 2024

(51) Int. Cl. H10K 59/80; H10K 59/12

(52) U.S. Cl. CPC H10K 59/879; H10K 59/1201

(57) ABSTRACT

A display module, including: a display panel; a color film layer, provided on a light-emitting side of the display panel, where the color film layer includes a plurality of light-filtering portions; and a micro-lens layer, provided on a side of the color film layer away from the display panel; where, the micro-lens layer includes a plurality of first converging lenses and a plurality of second converging lenses, a gap is provided between two adjacent first converging lenses, and an orthographic projection of a first converging lens on the display panel is located within an orthographic projection of a light-filtering portion on the display panel; a second converging lens is provided in the gap between two adjacent first converging lenses, and the second converging lens is connected to the first converging lens.

### CROSS REFERENCE TO RELATED APPLICATIONS

The present disclosure is based upon International Application No. PCT/CN2021/125420, filed on Oct. 21, 2021, the entire contents of which are incorporated herein by reference.

### TECHNICAL FIELD

The present disclosure relates to the field of display technology, and in particular, to a display module, a method for preparing the display module, and a display device including the display module.

### BACKGROUND

A micro-organic light-emitting diode (Micro-OLED) display has the advantages of small volume, light weight, high contrast, fast response speed, and low power consumption, etc. However, the Micro-OLED display generally has the problem of low light-emitting brightness, thereby limiting the widespread application of the Micro-OLED display in various fields.

It should be noted that the information disclosed in the above background part is only used to enhance the understanding of the background of the present disclosure, and therefore may include information that does not constitute related art known to those of ordinary skill in the art.

### SUMMARY

An objective of the present disclosure is to overcome the defects in the related art, and provide a display module, a method for preparing the display module, and a display device including the display module.

According to an aspect of the present disclosure, there is provided a display module, including:
a display panel;
a color film layer, provided on a light-emitting side of the display panel, where the color film layer includes a plurality of light-filtering portions; and
a micro-lens layer, provided on a side of the color film layer away from the display panel; where, the micro-lens layer includes a plurality of first converging lenses and a plurality of second converging lenses, a gap is provided between two adjacent first converging lenses, and an orthographic projection of a first converging lens on the display panel is located within an orthographic projection of a light-filtering portion on the display panel; a second converging lens is provided in the gap between two adjacent first converging lenses, and the second converging lens is connected to the first converging lens.

In some embodiments, an overlapping portion is provided between two adjacent light-filtering portions, and an orthographic projection of the overlapping portion on the display panel overlaps with an orthographic projection of the second converging lens on the display panel.

In some embodiments, on a cross section of the overlapping portion perpendicular to the display panel, an orthographic projection of a highest point of the overlapping portion away from the display panel on the display panel is located within the orthographic projection of the second converging lens on the display panel.

In some embodiments, a width of the second converging lens is less than 1/10 of a width of the first converging lens, and a height of the second converging lens is less than 1/10 of a height of the first converging lens.

In some embodiments, the display panel includes:
a substrate layer;
a first electrode, provided on a side of the substrate layer close to the color film layer;
a light-emitting layer, provided on a side of the first electrode away from the substrate layer; and
a second electrode, provided on a side of the light-emitting layer away from the substrate layer;
where an orthographic projection of the second converging lens on the substrate layer is at least partially located within a projection of an edge portion of the first electrode on the substrate layer.

In some embodiments, the second electrode includes a flat portion and a lower concave portion, and the orthographic projection of the second converging lens on the substrate layer is located within a projection of the lower concave portion on the substrate layer.

In some embodiments, a width of the first converging lens is greater than a maximum width of the first electrode.

In some embodiments, a height of the second converging lens is less than an interval between two adjacent first electrodes.

In some embodiments, an orthographic projection of the first converging lens on the substrate layer is located within an orthographic projection of the light-emitting layer on the substrate layer.

In some embodiments, the first converging lens is configured as a spherical segment structure, and the second converging lens is configured as a spherical segment structure.

In some embodiments, the micro-lens layer further includes:
a first flat plate layer, provided between the color film layer and the first converging lens; and
a second flat plate layer, provided between the color film layer and the second converging lens, where the second flat plate layer is integrally connected to the first flat plate layer.

In some embodiments, the first converging lens and the second converging lens satisfy a following relationship:

$$D - d = ( P - s ) / 2 ,$$

where P is a width of the light-filtering portion in a first direction, s is a width of the gap in the first direction, D is a sum of a height of the first converging lens and a height of the first flat plate layer, and d is a sum of a height of the second converging lens and a height of the second flat plate layer.

In some embodiments, a thickness and a refractive index of each film layer between a light-emitting surface of the display panel and the micro-lens layer satisfy a following relationship:

$$L = Σ L i n i \approx ( P - s ) / [ 2 \times ( n - 1 ) ] ,$$

where L is a light path between the light-emitting surface of the display panel and a surface of the micro-lens layer close to the display panel, n is a refractive index of the first converging lens, Li is the thickness of each film layer between the light-emitting surface of the display panel and the micro-lens layer, and ni is the refractive index of each film layer between the light-emitting surface of the display panel and the micro-lens layer.

In some embodiments, the display module further includes:
a first planarization layer, provided between the display panel and the color film layer; and
a second planarization layer, provided between the color film layer and the micro-lens layer.

According to another aspect of the present disclosure, there is provided a method for preparing a display module, including:
providing a display panel;
forming a color film layer on a light-emitting side of the display panel, where the color film layer includes a plurality of light-filtering portions; and
forming a micro-lens layer on a side of the color film layer away from the display panel, where the micro-lens layer includes a plurality of first converging lenses and a plurality of second converging lenses; a gap is provided between two adjacent first converging lenses, an orthographic projection of a first converging lens on the display panel is located within an orthographic projection of a light-filtering portion on the display panel, a second converging lens is formed in the gap between two adjacent first converging lenses, and the second converging lens is connected to the first converging lens.

In some embodiments, a first flat plate layer and a second flat plate layer are formed while forming the first converging lens and the second converging lens, the first flat plate layer is formed between the color film layer and the first converging lens, the second flat plate layer is formed between the color film layer and the second converging lens, and the second flat plate layer is connected to the first flat plate layer.

In some embodiments, forming the micro-lens layer on the side of the color film layer away from the display panel includes:

forming a micro-lens material layer on the side of the color film layer away from the display panel, then forming a preset pattern layer by performing patterned processing on the micro-lens material layer, and then forming the first converging lens, the second converging lens, the first flat plate layer and the second flat plate layer by baking the preset pattern layer.

In some embodiments, a baking temperature is greater than or equal to 100° C. and less than or equal to 130° C., and a baking time is greater than or equal to 50 minutes and less than or equal to 70 minutes.

According to yet another aspect of the present disclosure, there is provided a display device including any of the above display module.

The display module of the present disclosure includes a display panel, a color film layer and a micro-lens layer which are sequentially stacked; the color film layer includes a plurality of light-filtering portions, and the micro-lens layer includes a plurality of first converging lenses and a plurality of second converging lenses; a gap is provided between two adjacent first converging lenses, an orthographic projection of a first converging lens on the display panel is located within an orthographic projection of a light-filtering portion on the display panel, a second converging lens is provided in the gap between two adjacent first converging lenses, and the second converging lens is connected to the first converging lens. The light emitted from the light-filtering portion may be converged by the first converging lens, so that the diffusion angle of the light emitted from the first converging lens is small, thus improving the display brightness within an effective viewing angle. When there is provided a gap between two adjacent first converging lenses, the preparation process of the first converging lens can make the shape of the first converging lens more standard, thus ensuring the converging effect on the light and further improving the brightness. The second converging lens may converge the light emitted into the gap between two adjacent first converging lenses, thus further improving the brightness of the display module.

It should be understood that the above general description and the following detailed description are exemplary and explanatory only and are not intended to limit the present disclosure.

### BRIEF DESCRIPTION OF THE DRAWINGS

The accompanying drawings here, which are incorporated in and constitute a part of the description, illustrate embodiments consistent with the disclosure and together with the description serve to explain the principles of the disclosure. Obviously, the drawings in the following description are some embodiments of the present disclosure, and for those of ordinary skill in the art, other drawings can also be obtained from these drawings without creative efforts.

FIG. 1 is a schematic structural diagram of a display module according to some embodiments of the present disclosure.

FIG. 2 is a schematic top view of the color film layer in FIG. 1.

FIG. 3 is a schematic diagram showing a relative position of the color film layer and the light-emitting unit in FIG. 1.

FIG. 4 is a schematic diagram showing the relative positions of the micro-lens layer, the color film layer and the light-emitting unit in FIG. 1.

FIG. 5 is a schematic diagram of a light path of the micro-lens layer in FIG. 1.

FIG. 6 is a schematic diagram of a size relationship of the micro-lens layer in FIG. 1.

FIG. 7 is a schematic flowchart of a method for preparing a display module according to some embodiments of the present disclosure.

### DESCRIPTION OF THE REFERENCE NUMERALS

1, Display panel; 11, Substrate layer; 12, Back plate; 13, Third planarization layer; 14, First electrode; 141, Metal layer; 142, Transparent conductive layer; 143, Edge portion; 15, Pixel dielectric layer; 16, Light-emitting layer; 17, Second electrode; 171, Flat portion; 172, Lower concave portion; 18, Light-emitting unit;
2, Thin film encapsulation; 3, First planarization layer;
4, Color film layer; 41, Red light-filtering portion; 42, Green light-filtering portion; 43, Blue light-filtering portion; 44, Overlapping portion; 4a, Light-filtering portion;
5, Second planarization layer;
6, Micro-lens layer; 61, First converging lens; 62, Second converging lens; 63, First flat plate layer; 64, Second flat plate layer; 65, Gap;
7, Adhesive layer; 8, Cover plate.

### DETAILED DESCRIPTION

Example embodiments will now be described more fully with reference to the accompanying drawings. Example embodiments, however, can be implemented in various forms and should not be construed as limited to the embodiments set forth herein; by contrast, these embodiments are provided so that the present disclosure will be thorough and complete, and will fully convey the concept of example embodiments to those skilled in the art. The same reference numerals in the drawings denote the same or similar structures, and thus their detailed descriptions will be omitted. In addition, the drawings are merely schematic illustrations of the present disclosure, and are not necessarily drawn to scale.

Although relative terms such as “upper” and “lower” are used in the description to describe the relative relationship of one component to another component shown in the drawings, these terms are used in the description only for convenience, for example, according to the directions shown in the accompanying drawings. It will be appreciated that if the device shown in the drawings is turned over so that it is upside down, then the component described as being “upper” will become the component that is “lower”. When a structure is “on” another structure, it may mean that a structure is integrally formed on another structure, or that a structure is “directly” placed on another structure, or that a structure is “indirectly” placed on another structure through another structure.

The terms “a”, “an”, “the”, “said” and “at least one” are used to indicate the presence of one or more elements/components/etc.; the terms “comprising” and “including” are used to indicate an open inclusion and means that there may be additional elements/components/etc. in addition to the listed elements/components/etc.; the terms “first”, “second” and “third” etc. are only used as a marker, not a limit on the number of its objects.

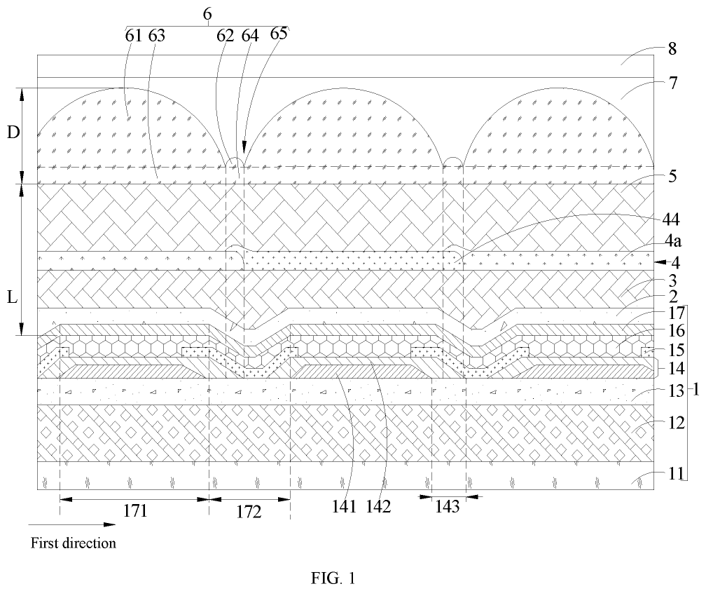

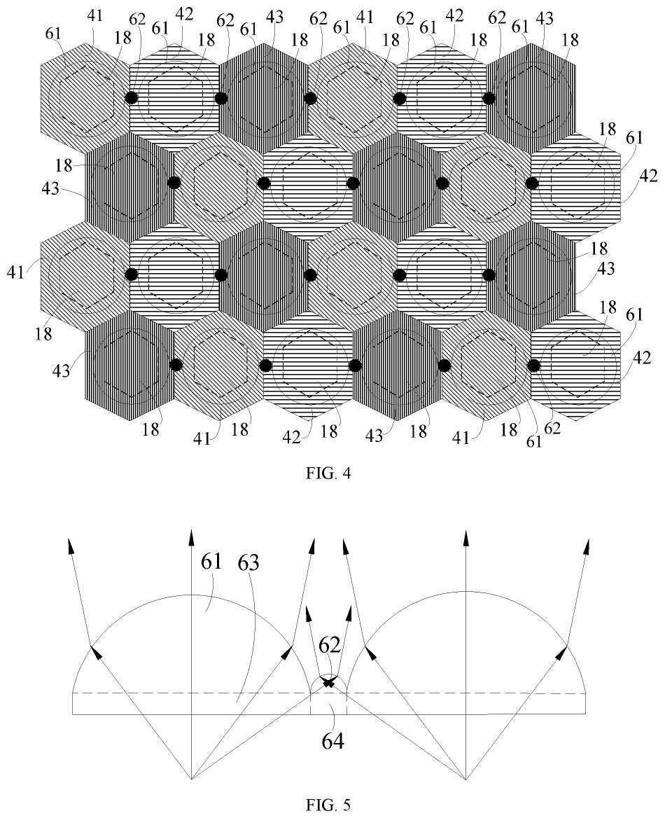

According to some embodiments of the present disclosure, there is provided a display module. Referring to FIG. 1 to FIG. 6, the display module may include a display panel 1, a color film layer, and a micro-lens layer 6; the color film layer is provided on the light-emitting side of the display panel 1, and the color film layer includes a plurality of light-filtering portions 4a; the micro-lens layer 6 includes a plurality of first converging lenses and a plurality of second converging lenses 62, a gap is provided between two adjacent first converging lenses, and an orthographic projection of a first converging lens on the display panel 1 is located within an orthographic projection of a light-filtering portions 4a on the display panel 1; a second converging lens 62 is provided in the gap 65 between two adjacent first converging lenses 61, and the second converging lens 62 is connected to the first converging lens 61.

According to the display module of the present disclosure, the light emitted from the light-filtering portion 4a may be converged by the first converging lens, so that the diffusion angle of the light emitted from the first converging lens is small, thus improving the display brightness within an effective viewing angle. When there is provided the gap 65 between two adjacent first converging lenses 61, the preparation process of the first converging lens 61 makes the shape of the first converging lens 61 more standard, thus ensuring the converging effect on the light and further improving the brightness. After a plurality of tests, the brightness improvement factor is about 1.4-1.6 times. The second converging lens 62 may converge the light emitted into the gap 65 between two adjacent first converging lenses 61, thus further improving the brightness of the display module.

In some embodiments, referring to FIG. 1, the display panel 1 may include a substrate layer 11, and the substrate layer 11 may be a wafer, sapphire, or the like. A back plate 12 is provided on a side of the substrate layer 11, the back plate 12 includes a plurality of switch structures arranged in an array, and the switch structure may include a gate, a source, a drain, or the like. That is, a monocrystalline silicon integrated circuit is used as the back plate. A third planarization layer 13 is provided on a side of the back plate 12 away from the substrate layer 11. The third planarization layer 13 may provide a relatively flat base plane for the first electrode 14 and the light-emitting layer 16 formed subsequently, which is beneficial to the light-emitting effect of the light-emitting layer 16.

A first electrode 14 is provided on a side of the third planarization layer 13 away from the substrate layer 11, and the first electrode 14 is electrically connected to a source or a drain in the switch structure. The first electrode 14 is configured as a two-layer structure; one layer close to the third planarization layer 13 is a metal layer 141, and the material of the metal layer 141 may be titanium, silver, or the like; one layer away from the third planarization layer 13 is a transparent conductive layer 142, and the material of the transparent conductive layer 142 may be indium tin oxide (ITO), indium zinc oxide (IZO), or the like. The transparent conductive layer 142 completely covers the metal layer 141, so that the edge portion 143 of the transparent conductive layer 142 protrudes from the metal layer 141. The edge portion 143 of the transparent conductive layer 142 forms the edge portion 143 of the first electrode 14.

The width of the first converging lens 61 is greater than the maximum width of the first electrode 14. For example, in the case that the first electrode 14 is a regular hexagon, the maximum width of the first electrode 14 is the length of the diagonal line between two opposite corners of the regular hexagon. In the case that the first electrode 14 is rectangular, the maximum width of the first electrode 14 is the length of the diagonal line of the rectangle. A spacing space is provided between two adjacent first electrodes 14, and the width of the spacing space in a first direction is the distance between two adjacent first electrodes 14.

A pixel dielectric layer 15 is provided on a side of the first electrode 14 away from the substrate layer 11. A first via hole is provided on the pixel dielectric layer 15, and the first via hole exposes a portion of the first electrode 14. A light-emitting layer 16 is provided on a side of the pixel dielectric layer 15 away from the substrate layer 11 and in the first via hole, the light-emitting layer 16 is set as an entire layer and completely covers the pixel dielectric layer 15 and the first electrode 14, and the light-emitting layer 16 is connected to the first electrode 14. The orthographic projection of the first converging lens 61 on the substrate layer 11 is located within the orthographic projection of the light-emitting layer 16 on the substrate layer 11.

A second electrode 17 is provided on a side of the light-emitting layer 16 away from the substrate layer 11, and the second electrode 17 is also connected to the light-emitting layer 16. The second electrode 17 includes a flat portion 171 and a lower concave portion 172. A portion of the second electrode 17 opposite to the metal layer 141 of the first electrode 14 forms the flat portion 171 of the second electrode 17, since the height of such portion of the first electrode 14 is substantially unchanged. For the portion of the second electrode 17 opposite to the edge portion 143 of the first electrode 14, since the height of the edge portion 143 of the first electrode 14 gradually decreases, the second electrode 17 is gradually concaved to form the lower concave portion 172, and the lowest position of the lower concave portion 172 is formed at a position opposite to the spacing space between two adjacent first electrodes 14.

The first electrode 14, the light-emitting layer 16, and the second electrode 17 form a light-emitting structure. The light-emitting layer 16 in a via hole forms a light-emitting unit 18; that is, the light-emitting structure includes a light-emitting unit 18. The light-emitting unit 18 can be driven and controlled through a switch structure.

In some embodiments, referring to FIG. 3, a cross section of the first via hole parallel to the substrate layer 11 may be configured as a regular hexagon, and a cross section of the light-emitting unit 18 parallel to the substrate layer 11 may be configured as a regular hexagon. Of course, in other example embodiments of the present disclosure, the cross section of the first via hole parallel to the substrate layer 11 may be configured as a rectangular, a circular, another regular polygon, etc. The cross section of the corresponding light-emitting unit 18 parallel to the substrate layer 11 may be configured as a rectangular, a circular, another regular polygon, etc.

The first electrode 14 may be an anode, and the second electrode 17 may be a cathode. The material of the first electrode 14 may be a conductive material including ITO (indium tin oxide), IZO (indium zinc oxide), or the like. The material of the second electrode 17 may be Mg, Ag, etc.

Continuing to refer to FIG. 1, a thin film encapsulation 2 (TFE) is provided on a side of the second electrode 17 away from the substrate layer 11. Since the material of the light-emitting layer 16 and the material of the cathode are relatively sensitive to water (H2O) and oxygen (O2), they are easy to oxidize; the thin film encapsulation 2 may achieve the effect of isolating water and oxygen to protect the display panel 1. The thin film encapsulation 2 may include an inorganic material layer and an organic material layer, and each film layer has good compactness. The number of layers of the inorganic material layer and the number of layers of the organic material layer as well as the relative position relationship may be configured according to needs.

In some embodiments, the first planarization layer 3 may be provided on the light-emitting side of the display panel 1; that is, the first planarization layer 3 may be provided on the side of the thin film encapsulation 2 away from the substrate layer 11. A color film layer 4 is provided on a side of the first planarization layer 3 away from the display panel 1; that is, the first planarization layer 3 is provided between the display panel 1 and the color film layer 4. The first planarization layer 3 provides a relatively flat base surface for the color film layer 4, so that the formed color film layer 4 is flatter; and the first planarization layer 3 may increase the adhesion between the color film layer 4 and the display panel 1. Of course, in some other example embodiments of the present disclosure, the first planarization layer 3 may not be provided in the condition that the flat shape of the thin film encapsulation 2 is good.

In some embodiments, referring to FIG. 1, the color film layer 4 may include a plurality of light-filtering portions 4a, and the plurality of light-filtering portions 4a may include a plurality of red light-filtering portions 41, a plurality of green light-filtering portions 42, and a plurality of blue light-filtering portions 43. An overlapping portion 44 is provided between two adjacent light-filtering portions 4a. For example, it may be that the edge portion of the red light-filtering portion 41 overlaps with the edge portion of the green light-filtering portion 42; it may also be that the edge portion of the green light-filtering portion 42 overlaps with the edge portion of the blue light-filtering portion 43; the portion where they overlap with each other forms the overlapping portion 44.

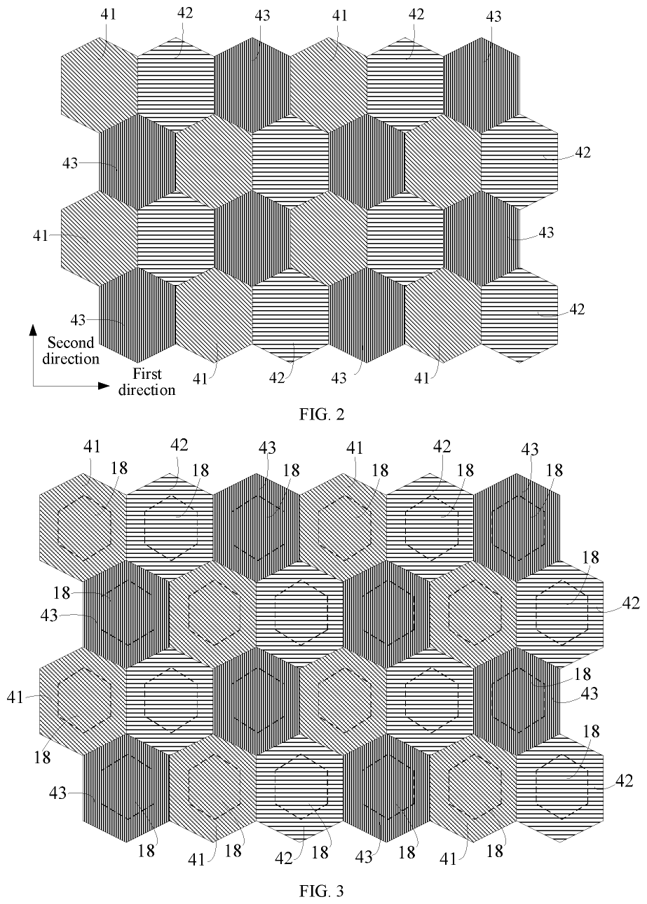

Referring to FIG. 2, the light-filtering portion 4a may also be configured as a regular hexagon, so that the plurality of light-filtering portions 4a may be densely distributed on the side of the first planarization layer 3 away from the display panel 1. Specifically, in a first direction, the red light-filtering portion 41, the green light-filtering portion 42, and the blue light-filtering portion 43 are sequentially arranged and circularly provided to form a row; a row of above light-filtering portions is sequentially arranged in a second direction, and two adjacent rows are provided in a staggered manner, so that the plurality of light-filtering portions can be densely provided. The first direction is perpendicular to the second direction. Of course, in other example embodiments of the present disclosure, the cross section of the light-filtering portion parallel to the substrate layer 11 may be configured as a rectangular, a circular, another regular polygon, etc.

Referring to FIG. 3, the light-filtering portion and the light-emitting unit 18 are in one-to-one correspondence; that is, one light-filtering portion corresponds to one light-emitting unit 18. The orthographic projection of the light-emitting unit 18 on the substrate layer 11 is located within the orthographic projection of the light-filtering portion on the substrate layer 11; that is, the area of the light-filtering portion is greater than the area of the light-emitting unit 18.

After being filtered through the color film layer 4, there may be monochromatic red light, blue light or green light passing through each light-filtering portion; that is, the light passing through the red light-filtering portion 41 is red light, and the light of other colors may be absorbed by the red light-filtering portion 41; the light passing through the blue light-filtering portion 43 is blue light, and the light of other colors may be absorbed by the blue light-filtering portion 43; and the light passing through the green light-filtering portion 42 is green light, and the light of other colors may be absorbed by the green light-filtering portion 42. Therefore, the brightness of the light emitted by the light-emitting unit 18 may be greatly reduced after passing through the color film layer 4. Specifically, the transmittance of the color film layer 4 is t, the aperture ratio (AR) of the light-filtering portion is a, the brightness of the white light emitted by the light-emitting unit 18 is L, and then the brightness LCF that may be felt by human eyes after passing through the color film layer 4 is τ×+×L. The transmittance of the color film layer 4 is about 18%-30%, and the aperture ratio is about 60%-70%. It can be seen through calculation that only about one quarter of the white light emitted by the light-emitting unit 18 is effectively utilized, resulting in a problem of lower brightness of the display module. However, in VR and AR fields, due to the factors such as low optical system efficiency or outdoor use, or the like, there are high requirements on the brightness of the Micro OLED micro-display.

Continuing to refer to FIG. 1, in some embodiments, a second planarization layer 5 may be provided on a side of the color film layer 4 away from the display panel 1, and a micro-lens layer 6 may be provided on a side of the second planarization layer 5 away from the display panel 1; that is, the second planarization layer 5 may be provided between the color film layer 4 and the micro-lens layer 6. The second planarization layer 5 provides a relatively flat base surface for the micro-lens layer 6, so that the formed micro-lens layer 6 is more standard, further improving the light converging effect, and further improving the brightness of the display module. Of course, in some other example embodiments of the present disclosure, the second planarization layer 5 may not be provided.

Continuing to refer to FIG. 1, in some example embodiments of the present disclosure, the micro-lens layer 6 may include a plurality of first converging lenses 61. A gap 65 is provided between two adjacent first converging lenses 61; that is, there is no connection between two adjacent first converging lenses 61. The orthographic projection of a first converging lens 61 on the display panel 1 is within the orthographic projection of a light-filtering portion 4a on the display panel 1; that is, the first converging lens 61 is in one-to-one correspondence to the light-filtering portion 4a. The maximum area of the cross section of the first converging lens 61 parallel to the display panel 1 is smaller than or equal to the area of the light-filtering portion 4a. The orthographic projection of the light-emitting unit 18 on the substrate layer 11 is located within the orthographic projection of the first converging lens 61 on the substrate layer 11; that is, the maximum area of the cross section of the first converging lens 61 parallel to the display panel 1 is greater than or equal to the area of the light-emitting unit 18.

The light emitted from the light-filtering portion 4a may be converged by the first converging lens 61, so that the diffusion angle of the light emitted from the first converging lens 61 is small, thus improving the display brightness within an effective viewing angle. Moreover, in order to better converge to a large angle of light, the first converging lens 61 should be made as large as possible. For example, the width of the first converging lens 61 may be greater than the maximum width of the first electrode 14, so that the larger first converging lens 61 may converge to light within a larger angle range in the case of a certain height from the light source. However, the preparation process of the first converging lens 61 determines that there is needed a certain gap 65 between two adjacent first converging lenses 61 so as to ensure that the first converging lens 61 has a better shape (which is beneficial to converging light). That is, when there is provided a gap 65 between two adjacent first converging lenses 61, the preparation process of the first converging lens 61 can make the shape of the first converging lens 61 more standard, thus ensuring the convergence effect on light and further improving the brightness.

The first converging lens 61 may be provided as a hemispheroid. Of course, in other example embodiments of the present disclosure, the first converging lens 61 may also be configured as greater than a hemispheroid or smaller than a hemispheroid. The first converging lens 61 is configured to be a spherical segment structure to converge the lights in various directions emitted from the light-filtering portion 4a, thus further improving the display brightness within the effective viewing angle.

In addition, in a case that the light-emitting unit 18 is a rectangular and the rectangle includes a short side of shorter length and a long side of longer length, in order to adapt to the light-emitting unit 18, the first converging lens 61 may be configured as a structure of a semi-ellipsoid, smaller than a semi-ellipsoid, or greater than a semi-ellipsoid, which may also achieve that the lights in various directions emitted from the light-filtering portion 4a are converged, thus further improving the display brightness within the effective viewing angle. Of course, the first converging lens 61 may be configured as a structure such as a semi-cylindrical, greater than a semi-cylindrical, or smaller than a semi-cylindrical, etc.

In some embodiments, there is a second converging lens 62 provided in the gap 65 between two adjacent first converging lenses 61.

Since there is provided a gap 65 between two adjacent first converging lenses 61, the light emitted into the gap 65 between two adjacent first converging lenses 61 cannot be converged; therefore, the improvement value of the brightness of the display module by the first converging lens 61 is not ideal enough. The light emitted into the gap 65 between two adjacent first converging lenses 61 may be converged by the second converging lens 62, thus further improving the brightness of the display module.

The width of the second converging lens 62 is less than 1/10 of the width of the first converging lens 61, and the height of the second converging lens 62 is less than 1/10 of the height of the first converging lens 61, such that the second converging lens 62 has a very small volume relative to the first converging lens 61. The convergence of light is mainly achieved by the first converging lens 61, and the second converging lens 62 mainly plays an auxiliary role. The second converging lens 62 is configured to be small enough to avoid the influence of the second converging lens 62 on the first converging lens 61. That is to avoid the influence of the main light-emitting region.

Moreover, referring to FIG. 1, the orthographic projection of the overlapping portion 44 between two adjacent light-filtering portions 4a on the display panel 1 overlaps with the orthographic projection of the second converging lens 62 on the display panel 1. Specifically, the red light-filtering portion and the green light-filtering portion are two adjacent light-filtering portions, and the orthographic projection of the overlapping portion 44 between the red light-filtering portion and the green light-filtering portion on the display panel 1 overlaps with the orthographic projection of the second converging lens 62 on the display panel 1. Referring to FIG. 5, it makes that the second converging lens 62 may refract the light of different colors emitted from the red light-filtering portion and the green light-filtering portion, and refract the light emitted from the red light-filtering portion toward the side of the red light-filtering portion, and refract the light emitted from the green light-filtering portion toward the side of the green light-filtering portion, thus reducing color crosstalk between the red light-filtering portion and the green light-filtering portion, and preventing color cast from being generated at a large viewing angle. Of course, there are the same beneficial effects on the light-filtering portions of other colors.

In addition, the highest point of the overlapping portion 44 away from the display panel 1 is generally located in the middle of the overlapping portion 44. On a cross section of overlapping portion 44 perpendicular to the display panel 1, the orthographic projection of highest point of the overlapping portion 44 away from the display panel 1 on the display panel 1 is located within the orthographic projection of the second converging lens 62 on the display panel 1, so that the second converging lens 62 is basically located in the middle of the overlapping portion 44. The refraction effects of the second converging lens 62 on the light emitted from two adjacent light-filtering portions 4a are basically the same, without one of the refraction angles being large and the other one of the refraction angles being small, so as to avoid a bad color cast.

Moreover, the overlapping portion 44 is opaque. For example, since the light emitted from the green light-filtering portion 42 is green light which is completely absorbed by the red light-filtering portion 41 after passing through the red light-filtering portion 41 that overlaps with the green light-filtering portion 41, so that no light is emitted from the red light-filtering portion 41, and no light is emitted from the overlapping portion 44, thus the overlapping portion 44 is opaque. Therefore, the light emitted along the light-filtering portion at the edge of the overlapping portion 44 forms an image of the overlapping portion 44, and the converging effect of the second converging lens 62 on the light makes the image of the overlapping portion 44 reduced, so that the area of the opaque region incident into human eyes is reduced, thus improving the aperture ratio of the display module.

In some other example embodiments of the present disclosure, the orthographic projection of the second converging lens 62 on the substrate layer 11 is at least partially located within the projection of the edge portion 143 of the first electrode 14 on the substrate layer 11. That is, the orthographic projection of the second converging lens 62 on the substrate layer 11 may be all located within the projection of the edge portion 143 of the first electrode 14 on the substrate layer 11, and the orthographic projection of the second converging lens 62 on the substrate layer 11 may also be partially located within the projection of the edge portion 143 of the first electrode 14 on the substrate layer 11, so that the second converging lens 62 is located at the edge of the light-emitting unit 18, and the second converging lens 62 is prevented from affecting the light path of the first converging lens 61, that is, avoiding the influence on the main light-emitting region.

In still some example embodiments of the present disclosure, the orthographic projection of the second converging lens 62 on the substrate layer 11 is located within the projection of the lower concave portion 172 on the substrate layer 11, so that the second converging lens 62 is located at the edge of the light-emitting unit 18, and the second converging lens 62 is prevented from affecting the light path of the first converging lens 61; that is, avoiding the influence on the main light-emitting region. In addition, it makes that the second converging lens 62 is basically located in the middle of two adjacent light-emitting units 18, and the refraction effects of the second converging lens 62 on the light emitted from two adjacent light-emitting units 18 are basically the same, thus avoiding a bad color cast.

In still other example embodiments of the present disclosure, the height of the second converging lens 62 is less than the interval between two adjacent first electrodes 14. It makes that the second converging lens 62 is small enough to prevent the second converging lens 62 from affecting the first converging lens 61; that is, avoiding the influence on the main light-emitting region.

The second converging lens 62 may be provided as a hemispheroid. Of course, in other example embodiments of the present disclosure, the second converging lens 62 may also be configured as greater than a hemispheroid or smaller than a hemispheroid. The second converging lens 62 is configured as a spherical segment structure to converge the lights in various directions emitted from the light-filtering portion 4a, thus further improving the display brightness within the effective viewing angle.

In addition, since the separating line between the two adjacent light-filtering portions 4a is generally a strip, in order to adapt to the separating line, the second converging lens 62 may be configured as a structure of a semi-ellipsoid, smaller than a semi-ellipsoid, or greater than a semi-ellipsoid, which may also achieve that the lights in various directions emitted from the light-filtering portion 4a are converged, thereby further improving the display brightness within the effective viewing angle. Furthermore, the color crosstalk between two adjacent light-filtering portions 4a can be reduced within a longer range, thus preventing color cast from being generated at a large viewing angle. Of course, the second converging lens 62 may be configured as a structure such as a semi-cylindrical, greater than a semi-cylindrical, or smaller than a semi-cylindrical, etc.

In some embodiments of the present disclosure, the micro-lens layer 6 may further include a first plate layer 63 and a second plate layer 64; the first plate layer 63 is provided between the color film layer 4 and the first converging lens 61; the second plate layer 64 is provided between the color film layer 4 and the second converging lens 62; the second plate layer 64 is connected to the first plate layer 63; and the first plate layer 63 and the second plate layer 64 as well as the micro-lens layer 6 may be formed through the same patterning process. By providing the first flat plate layer 63 and the second flat plate layer 64, it may avoid damage to the first planarization layer 3 when the first converging lens 61 and the second converging lens 62 are formed; and the process operation is facilitated, the process difficulty is reduced, and the efficiency is improved.

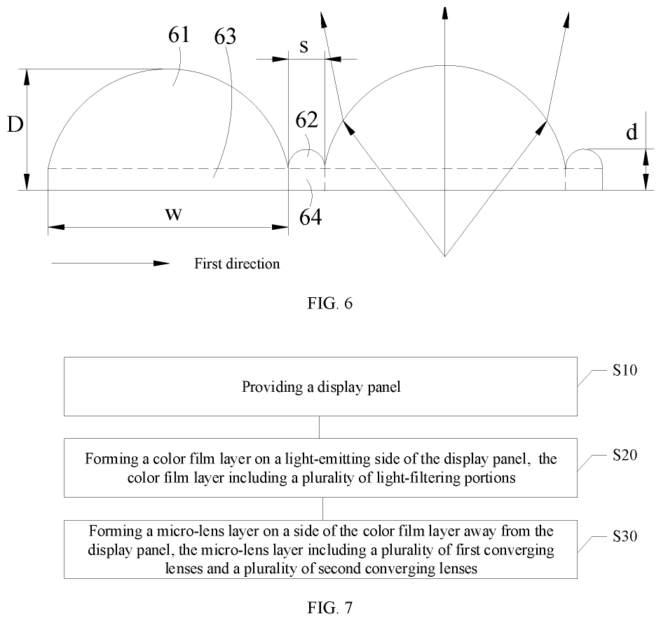

Referring to FIG. 1 and FIG. 6, since the second converging lens 62 is provided between two adjacent first converging lenses 61, and the orthographic projection of the separating line between two adjacent filtering portions 4a on the display panel 1 is at least partially located within the orthographic projection of the second converging lens 62 on the display panel 1, therefore, w+s=P. In the formula, P is the width of the light-filtering portion 4a in the first direction, which has been determined during design and is a known number. s is the width of the gap 65 in the first direction, which is also the width of the second converging lens 62 in the first direction and is determined by the limit of the resolution of the first converging lens 61; that is, s is determined by the size of the aperture of the photolithography mask (the material of the micro-lens material layer is a positive photoresist, and the photosensitive portion is removed during development) and is a known number. w is the width of the first converging lens 61 in the first direction, which may be calculated according to the two known numbers.

The light path between the light-emitting surface of the display panel 1 and the surface of the micro-lens layer 6 close to the display panel 1 is L=ΣLini. In the formula, Li is the thickness of each film layer between the light-emitting surface of the display panel 1 and the micro-lens layer, and ni is the refractive index of each film layer between the light-emitting surface of the display panel 1 and the micro-lens layer.

Since the first converging lens 61 is a hemispheroid, the first converging lens 61 and the second converging lens 62 satisfy a following relationship:

$$D - d = ( P - s ) / 2.$$

In the formula, D is the sum of the height of the first converging lens 61 and the height of the first flat plate layer 63, and d is the sum of the height of the second converging lens 62 and the height of the second flat plate layer 64.

Moreover, the object focal length f of the first converging lens 61 of the hemispheroid is approximately as follows:

$$1 / f = 2 \times ( n - 1 ) / ( P - s ) .$$

In the formula, n is the refractive index of the first converging lens 61.

The light-emitting surface of the light-emitting layer 16 is provided on the object focal plane, and L=f. Therefore, it can be obtained that the thickness and the refractive index of each film layer between the light-emitting surface of the display panel 1 and the micro-lens layer satisfy the following relationship:

$$L = \sum L ini \approx ( P - s ) / [ 2 \times ( n - 1 ) ] .$$

In the formula, L is the light path between the light-emitting surface of the display panel 1 and the surface of the flat plate layer close to the display panel 1. The width P of the light-filtering portion 4a in the first direction, the width s of the gap 65 in the first direction, and the refractive index n of the first converging lens 61 are all known numbers. Therefore, the thickness and the refractive index of each film layer between the light-emitting surface of the display panel 1 and the micro-lens layer can be adjusted according to the above formula, so as to satisfy the requirement of the above formula.

In some embodiments, the display module may further include an adhesive layer 7. The adhesive layer 7 is provided on a side of the micro-lens layer 6 away from the display panel 1, and the material of the adhesive layer 7 may be an optically clear adhesive (OCA).

In some embodiments, the display module may further include a cover plate 8. The cover plate 8 is provided on a side of the adhesive layer 7 away from the display panel 1; that is, the cover plate 8 is bonded to the micro-lens layer 6 through the adhesive layer 7. The cover plate 8 plays a role of protecting the display module.

Based on the same inventive concept, according to example embodiments of the present disclosure, there is provided a method for preparing a display module. With reference to the flowchart of the method for preparing the display module of the present disclosure as shown in FIG. 7, the method for preparing the display module may include the following steps.

In step S10, a display panel 1 is provided.

In step S20, a color film layer 4 is formed on a light-emitting side of the display panel 1, and the color film layer 4 includes a plurality of light-filtering portions 4a.

In step S30, a micro-lens layer 6 is formed on a side of the color film layer 4 away from the display panel 1, and the micro-lens layer 6 includes a plurality of first converging lenses 61 and a plurality of second converging lenses 62.

Among them, there is provided a gap 65 between two adjacent first converging lenses 61, and an orthographic projection of a first converging lens 61 on the display panel 1 is located within an orthographic projection of a light-filtering portion 4a on the display panel 1. A second converging lens 62 is provided in the gap 65 between two adjacent first converging lenses 61, and the second converging lens 62 is connected to the first converging lens 61.

Various steps of the method for preparing the display module are described in detail below.

The method for preparing the display panel 1 adopts the current existing preparation method, and therefore, details are not described here again.

The first planarization layer 3 is formed on the light-emitting side of the display panel 1 through the method of deposition, coating, or the like

Firstly, a red light-filtering material layer is formed on the side of the first planarization layer 3 away from the display panel 1 through the method of deposition, coating, or the like. Then, the red light-filtering material layer is subjected to photolithography to form the red light-filtering portion 41.

Next, a green light-filtering material layer is formed on the side of the first planarization layer 3 away from the display panel 1 through the method of deposition, coating, or the like. Then, the green light-filtering material layer is subjected to photolithography to form the green light-filtering portion 42.

Furthermore, a blue light-filtering material layer is formed on the side of the first planarization layer 3 away from the display panel 1 through the method of deposition, coating, or the like. Then, the blue light-filtering material layer is subjected to photolithography to form the blue light-filtering portion 43.

It should be noted that the order to form the red light-filtering portion 41, the green light-filtering portion 42, and the blue light-filtering portion 43 may be changed as needed.

Since the red light-filtering material, the green light-filtering material and the blue light-filtering material are all negative photoresist, there will be a certain expansion during development, so that there is a certain overlap between the light-filtering portions 4a of different colors. The height of the overlapping portion is higher than the height of the non-overlapping portion, so that the surface of the color film layer 4 is uneven.

The second planarization layer 5 is formed on the side of the color film layer 4 away from the display panel 1 through the method of deposition, coating, or the like. The second planarization layer 5 may provide a relatively flat base surface for the subsequently formed micro-lens layer.

The micro-lens material layer is formed on the side of the second planarization layer 5 away from the display panel 1 through the method of deposition, coating, or the like. The micro-lens material layer is made of an organic resin, and the thickness of the micro-lens material layer is D1 (D) is greater than D1, and the difference between D and D1 is about 0.1 μm to 0.2 μm). Then, the micro-lens material layer is subjected to photolithography to form a preset pattern layer. However, the exposure time or the light intensity during exposure is reduced, so that the micro-lens material layer retains a layer with a thickness of d1 (dis greater than d1, and a difference between d and d1 is about 0.05 μm to 0.15 μm); that is, the preset pattern layer includes a flat plate layer and a protruding portion, and the protruding portion is formed on the side of the flat plate layer away from the display panel 1. Secondly, baking is performed; the baking time is greater than or equal to 50 minutes and less than or equal to 70 minutes; for example, the baking time may be 60 minutes; the baking temperature is greater than or equal to 100° C. and less than or equal to 130° C.; for example, the baking temperature may be 115° C. Finally, natural cooling is performed. During baking, the micro-lens material layer may expand to a certain extent, so that the protruding portion forms the first converging lens 61, and the gap between the two first converging lenses 61 is small. The flat plate layer in the gap is not prone to diffusing during baking expansion so as to form the second converging lens 62, and the flat plate layers at other positions are prone to diffusing during baking expansion so as not to form the second converging lens 62.

It should be noted that, although the various steps of the method for preparing the display module in the present disclosure are described in a specific order in the drawings, this does not require or imply that these steps must be performed in this specific order, or that all the illustrated steps must be performed to achieve the desired results. Additionally or alternatively, some steps may be omitted, a plurality of steps may be combined into one step to be performed, and/or one step may be decomposed into a plurality of steps for execution, etc.

Based on the same inventive concept, according to example embodiments of the present disclosure, there is provided a display device. The display device may include any of the above-mentioned display module. The specific structure of the display module has been described in detail above, and therefore, details are not described here again.

The specific type of the display device is not particularly limited, which may be a common display device type in the art; specifically, for example, it may be a mobile device such as a mobile phone, a wearable device such as a watch, an AR (augmented reality)/VR (virtual reality) device, etc. Those skilled in the art may correspondingly select according to the specific use of the display device, which will not be repeated here. In particular, AR/VR technology tends to mature, getting more and more attention to the consumer market and manufacturing industry, and the market share of AR/VR in 2025 years is expected to exceed 1,000 billion dollars.

It should be noted that, in addition to the display panel 1, the display device further includes other necessary components and compositions, specifically such as a housing, a circuit board, a power line, or the like, by taking the display as an example. Those skilled in the art may correspondingly supplement according to the specific use requirements of the display device, and details are not described here again.

Compared with the related art, the beneficial effects of the display device provided by the embodiments of the present disclosure are the same as the beneficial effects of the display module provided by the above example embodiments, and details are not described here.

Other embodiments of the present disclosure will be apparent to those skilled in the art from consideration of the specification and practice of the disclosure disclosed here. The present disclosure is intended to cover any variations, uses, or adaptations of the present disclosure following the general principles of the present disclosure and including common general knowledge or conventional technical means in the art not disclosed in the present disclosure. The specification and embodiments are considered as examples only, with a true scope and spirit of the disclosure being indicated by the appended claims.

1. A display module, comprising:
a display panel;
a color film layer, provided on a light-emitting side of the display panel, wherein the color film layer comprises a plurality of light-filtering portions; and
a micro-lens layer, provided on a side of the color film layer away from the display panel; wherein, the micro-lens layer comprises a plurality of first converging lenses and a plurality of second converging lenses, a gap is provided between two adjacent first converging lenses, and an orthographic projection of a first converging lens on the display panel is located within an orthographic projection of a light-filtering portion on the display panel; a second converging lens is provided in the gap between two adjacent first converging lenses, and the second converging lens is connected to the first converging lens.

2. The display module according to claim 1, wherein an overlapping portion is provided between two adjacent light-filtering portions, and an orthographic projection of the overlapping portion on the display panel overlaps with an orthographic projection of the second converging lens on the display panel.

3. The display module according to claim 2, wherein, on a cross section of the overlapping portion perpendicular to the display panel, an orthographic projection of a highest point of the overlapping portion away from the display panel on the display panel is located within the orthographic projection of the second converging lens on the display panel.

4. The display module according to claim 1, wherein a width of the second converging lens is less than 1/10 of a width of the first converging lens, and a height of the second converging lens is less than 1/10 of a height of the first converging lens.

5. The display module according to claim 1, wherein the display panel comprises:
a substrate layer;
a first electrode, provided on a side of the substrate layer close to the color film layer;
a light-emitting layer, provided on a side of the first electrode away from the substrate layer; and
a second electrode, provided on a side of the light-emitting layer away from the substrate layer;
wherein an orthographic projection of the second converging lens on the substrate layer is at least partially located within a projection of an edge portion of the first electrode on the substrate layer.

6. The display module according to claim 5, wherein the second electrode comprises a flat portion and a lower concave portion, and the orthographic projection of the second converging lens on the substrate layer is located within a projection of the lower concave portion on the substrate layer.

7. The display module according to claim 5, wherein a width of the first converging lens is greater than a maximum width of the first electrode.

8. The display module according to claim 5, wherein a height of the second converging lens is less than an interval between two adjacent first electrodes.

9. The display module according to claim 5, wherein an orthographic projection of the first converging lens on the substrate layer is located within an orthographic projection of the light-emitting layer on the substrate layer.

10. The display module according to claim 1, wherein the first converging lens is configured as a spherical segment structure, and the second converging lens is configured as a spherical segment structure.

11. The display module according to claim 1, wherein the micro-lens layer further comprises:
a first flat plate layer, provided between the color film layer and the first converging lens; and
a second flat plate layer, provided between the color film layer and the second converging lens, wherein the second flat plate layer is integrally connected to the first flat plate layer.

12. The display module according to claim 11, wherein the first converging lens and the second converging lens satisfy a following relationship:
$$D - d = ( P - s ) / 2 ,$$
wherein P is a width of the light-filtering portion in a first direction, s is a width of the gap in the first direction, D is a sum of a height of the first converging lens and a height of the first flat plate layer, and dis a sum of a height of the second converging lens and a height of the second flat plate layer.

13. The display module according to claim 12, wherein a thickness and a refractive index of each film layer between a light-emitting surface of the display panel and the micro-lens layer satisfy a following relationship:
$$L = Σ {L}_{i} {n}_{i} \approx ( P - s ) / [ 2 \times ( n - 1 ) ] ,$$
wherein L is a light path between the light-emitting surface of the display panel and a surface of the micro-lens layer close to the display panel, n is a refractive index of the first converging lens, L; is the thickness of each film layer between the light-emitting surface of the display panel and the micro-lens layer, and nᵢ is the refractive index of each film layer between the light-emitting surface of the display panel and the micro-lens layer.

14. The display module according to claim 1, further comprising:
a first planarization layer, provided between the display panel and the color film layer; and
a second planarization layer, provided between the color film layer and the micro-lens layer.

15. A method for preparing a display module, comprising:
providing a display panel;
forming a color film layer on a light-emitting side of the display panel, wherein the color film layer comprises a plurality of light-filtering portions; and
forming a micro-lens layer on a side of the color film layer away from the display panel, wherein the micro-lens layer comprises a plurality of first converging lenses and a plurality of second converging lenses;
wherein a gap is provided between two adjacent first converging lenses, an orthographic projection of a first converging lens on the display panel is located within an orthographic projection of a light-filtering portion on the display panel, a second converging lens is formed in the gap between two adjacent first converging lenses, and the second converging lens is connected to the first converging lens.

16. The method for preparing the display module according to claim 15, wherein a first flat plate layer and a second flat plate layer are formed while forming the first converging lens and the second converging lens, the first flat plate layer is formed between the color film layer and the first converging lens, the second flat plate layer is formed between the color film layer and the second converging lens, and the second flat plate layer is connected to the first flat plate layer.

17. The method for preparing the display module according to claim 16, wherein forming the micro-lens layer on the side of the color film layer away from the display panel comprises:
forming a micro-lens material layer on the side of the color film layer away from the display panel, then forming a preset pattern layer by performing patterned processing on the micro-lens material layer, and then forming the first converging lens, the second converging lens, the first flat plate layer and the second flat plate layer by baking the preset pattern layer.

18. The method for preparing the display module according to claim 17, wherein a baking temperature is greater than or equal to 100° C. and less than or equal to 130° C., and a baking time is greater than or equal to 50 minutes and less than or equal to 70 minutes.

19. A display device, comprising a display module, wherein the display module comprises:
a display panel;
a color film layer, provided on a light-emitting side of the display panel, wherein the color film layer comprises a plurality of light-filtering portions; and
a micro-lens layer, provided on a side of the color film layer away from the display panel; wherein, the micro-lens layer comprises a plurality of first converging lenses and a plurality of second converging lenses, a gap is provided between two adjacent first converging lenses, and an orthographic projection of a first converging lens on the display panel is located within an orthographic projection of a light-filtering portion on the display panel; a second converging lens is provided in the gap between two adjacent first converging lenses, and the second converging lens is connected to the first converging lens.

20. The display device according to claim 19, wherein an overlapping portion is provided between two adjacent light-filtering portions, and an orthographic projection of the overlapping portion on the display panel overlaps with an orthographic projection of the second converging lens on the display panel.
